(19) United States
(12) Patent Application Publication
(10) Pub. No.: US 2014/0334114 A1
(43) Pub. Date: Nov. 13, 2014

(54) DEVICE HOUSING OF ELECTRONIC DEVICE AND METHOD FOR MAKING THE SAME

(71) Applicants: FIH (Hong Kong) Limited, Kowloon (HK); SHENZHEN FUTAIHONG PRECISION INDUSTRY CO., LTD., Shenzhen (CN)

(72) Inventors: NAI-LIN YANG, New Taipei (TW); BING ZHANG, Shenzhen (CN)

(73) Assignees: FIH (Hong Kong) Limited, Kowloon (HK); SHENZHEN FUTAIHONG PRECISION INDUSTRY CO., LTD., Shenzhen (CN)

(21) Appl. No.: 14/061,289

(22) Filed: Oct. 23, 2013

(30) Foreign Application Priority Data
May 10, 2013 (CN) 2013101708164

(51) Int. Cl. H05K 7/14; H05K 13/00

(52) U.S. Cl. CPC H05K 7/1417; H05K 13/00
USPC 361/752; 264/265

(57) ABSTRACT

A device housing of an electronic device includes a main body and a reinforcing plate. The reinforcing plate includes a plate portion and at least one buffer body. The plate portion is integrally formed in the main body, and the at least one buffer body is formed on the plate portion. The main body is assembled with a circuit board of the electronic device. The at least one buffer body elastically resists against with the circuit board.

### BACKGROUND

1. Technical Field

The present disclosure relates to a device housing of an electronic device and a method for making the device housing.

2. Description of Related Art

Currently, portable electronic device such as mobile phones, laptop computers and personal digital assistants (PDAs) are in widespread use and incorporate plastic housings. However, electronic elements of the portable electronic devices received in such housings may be easily damaged if the devices are dropped.

Therefore, there is room for improvement within the art.

### BRIEF DESCRIPTION OF THE DRAWINGS

Many aspects of the present disclosure can be better understood with reference to the following figures. The components in the figures are not necessarily drawn to scale, the emphasis instead being placed upon clearly illustrating the principles of the disclosure.

FIG. 1 is an exploded, schematic view of an electronic device including a device housing and a circuit board, according to an exemplary embodiment.

FIG. 2 is an assembled view of the electronic device in FIG. 1.

FIG. 3 is a cross-sectional view of the electronic device in FIG. 2 taken along a line III-III.

FIG. 4 is similar to FIG. 3, but showing a state of the electronic device when the buffer body is pressed.

### DETAILED DESCRIPTION

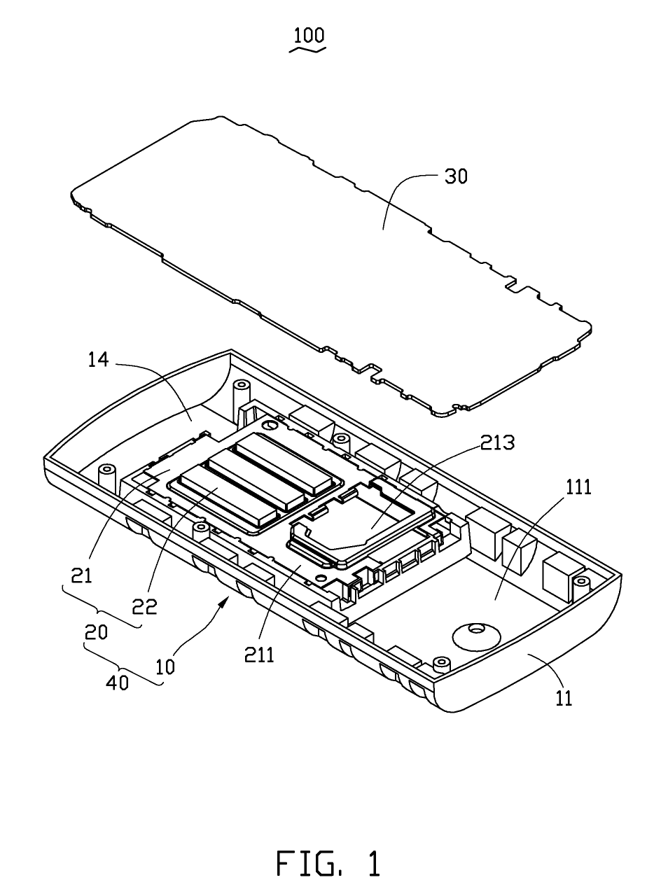

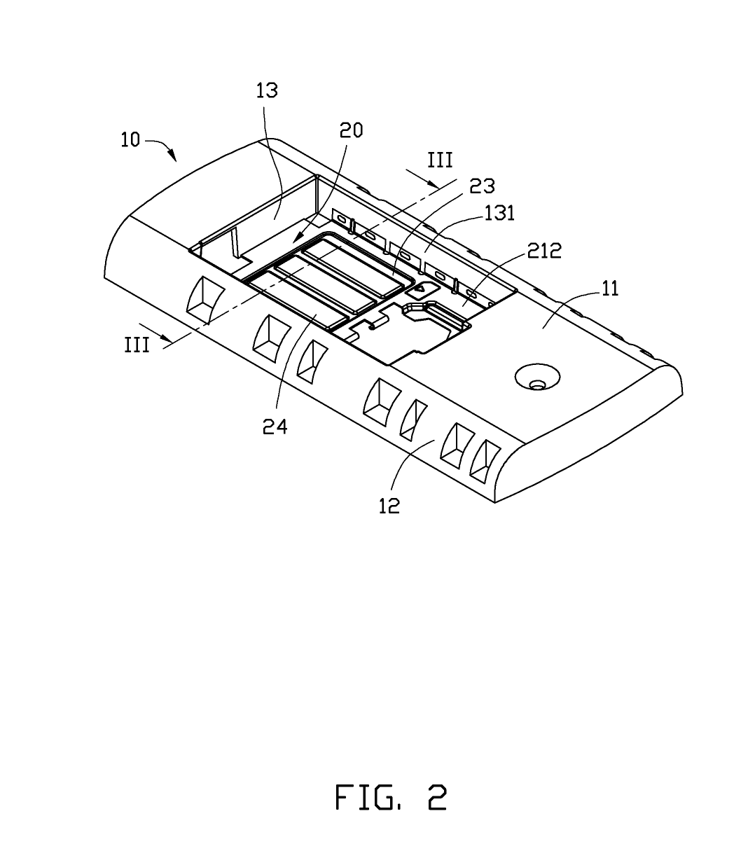

FIGS. 1 and 2 show a schematic view of an electronic device 100, according to an exemplary embodiment. The electronic device 100 may be a mobile phone, a personal digital assistant, or a laptop computer. The electronic device 100 includes a circuit board 30 and a device housing 40. The device housing 40 includes a main body 10 and a reinforcing plate 20. The circuit board 30 is mounted on the main body 10.

The main body 10 includes a base 11, a peripheral wall 12, and a battery accommodating cavity 13. The base 11 has a rear surface 111 at one side. The peripheral wall 12 extends from the periphery of the rear surface 111. The rear surface 111 and the peripheral wall 12 cooperatively form a receiving cavity 14 for mounting the circuit board 30. The battery accommodating cavity 13 is defined at another side of the base 11 opposite to the rear surface 111 for receiving a battery (not shown). The battery accommodating cavity 13 includes an inner wall 131.

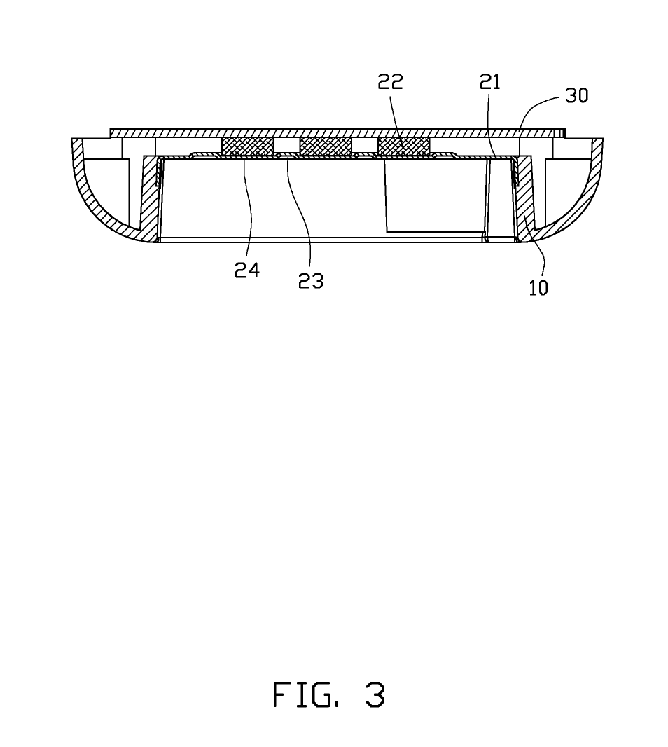

FIG. 3 shows that the reinforcing plate 20 includes a plate portion 21 and at least one buffer body 22 fixed on the plate portion 21 by adhesive or injection molding. The plate portion 21 may be made of metal material, such as iron, aluminum, aluminum alloy, or copper, for example. The plate portion 21 includes a first surface 211 and a second surface 212 opposite to the first surface 211. In this exemplary embodiment, the first surface 211 is exposed from the receiving cavity 14 and the second surface 212 is exposed from the battery accommodating cavity 13. The second surface 212 and the inner wall 131 cooperatively form the battery accommodating cavity 13. A groove 23 is defined on the second surface 212 of the plate portion 21. At least one supporting portion 24 is formed on a bottom surface of the groove 23 for increasing the strength of the plate portion 21. In this exemplary embodiment, there are three supporting portions 24. The three supporting portions 24 protrude and extend out of the groove 23 until a surface of the supporting portions 24 is level with the other area of the second surface 212 without the groove 23 for ensuring the second surface 212 of the plate portion 21 is flat so that the second surface 212 of the plate portion 21 can effectively and steady support other electronic elements of the electronic device 100 (e.g., a battery). The plate portion 21 further defines a hole 213 adjacent to the groove 23 for receiving a chip card structure (not shown).

In this exemplary embodiment, there are three buffer bodies 22. Each buffer body 22 may be made of an elastic material, such as rubber, thermoplastic polyurethanes (TPU), thermoplastic elastomeric (TPE), or polyimide, for example. The three buffer bodies 22 are fixed on the first surface 211 opposite to the groove 23 for supporting the circuit board 30.

A method for making the device housing 40 may include the following steps.

First, a metal sheet is punched into a predetermined shape to form the plate portion 21. The plate portion 21 defines a groove 23 and a hole 213 adjacent to the groove 23. At least one supporting portion 24 is formed in the groove 23.

Then, an injection mold (not shown) having a cavity formed therein is provided. The punched plate portion 21 is placed into the mold. A first molding material (e.g., molten plastic or resin) is injected into the mold cavity and is cooled to form the main body 10 bonded with the plate portion 21.

After that, a second molding material is injected into the mold cavity of the mold to form the buffer bodies 22 on the first surface 211 opposite to the groove 23. The buffer bodies 22 combine the plate portion 21 and the main body 10 to form the device housing 40. In the exemplary embodiment, the second molding material may be made of elastic material, such as rubber, thermoplastic polyurethanes (TPU), thermoplastic elastomeric (TPE), or polyimide, for example. Finally, the device housing 40 is formed and removed from the mold cavity.

It can be understood that the buffer bodies 22 can also be directly mounted on the first surface 211 opposite to the groove 23 by adhesive.

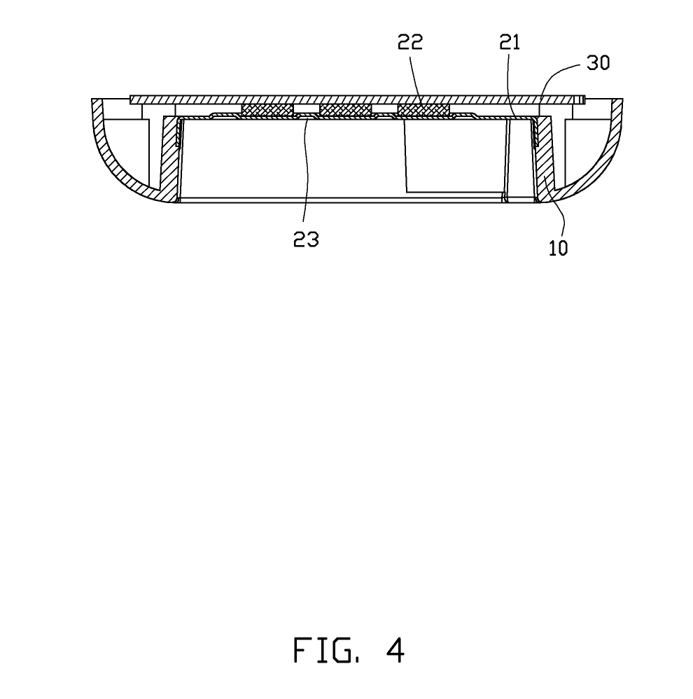

FIG. 3 shows that in assembly, the circuit board 30 is received in the receiving groove and is held by the buffer bodies 22. FIG. 4 shows that when the device housing 40 is subjected to impact or fall, the circuit board 30 generates an impact force towards the main body 10. The plate portion 21 enhances strength of the main body 10, and the buffer bodies 22 can have a buffering role for the circuit board 30. In addition, a chip card structure of the electronic device 100 can be formed on the plate portion 21 to more stably support the chip card.

In summary, the device housing 40 includes a main body 10 and a reinforcing plate 20 formed on the main body 10. The plate portion 21 of the reinforcing plate 20 is made of metal material and is integrally formed on the main body 10, which will enhance strength of the device housing 40. In addition, the buffer bodies 22 can have buffering role for the circuit board 30, thereby effectively supporting the circuit board 30 to prevent the electronic elements of the electronic device 100 (e.g., the circuit board 30) from damage.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing of an electronic device comprising:
a main body; and
a reinforcing plate comprising a plate portion and at least one buffer body, the plate portion integrally formed in the main body, the at least one buffer body formed on the plate portion;
wherein the main body is assembled with a circuit board of the electronic device, and the at least one buffer body elastically resists against the circuit board.

2. The device housing of claim 1, wherein the at least one buffer body is made of elastic material.

3. The device housing of claim 1, wherein the plate portion is formed by punching a metal sheet into a predetermined shape.

4. The device housing of claim 1, wherein the plate portion comprises a first surface and a second surface opposite to the first surface, the at least one buffer body is fixed on the first surface by adhesive or injection molding.

5. The device housing of claim 4, wherein a groove is defined on the second surface, at least one supporting portion is formed on a bottom surface of the groove to increase a strength of the plate portion.

6. The device housing of claim 5, wherein the at least one supporting portion protrude and extend out of the groove until a surface of the at least one supporting portion is level with the other area of the second surface without the groove.

7. The device housing of claim 5, wherein the plate portion further defines a hole adjacent to the groove for receiving a chip card structure.

8. The device housing of claim 4, wherein the main body comprises a base and a peripheral wall, the base comprises a rear surface, the peripheral wall extends from the periphery of the rear surface, the rear surface and the peripheral wall cooperatively form a receiving cavity for receiving the circuit board; the first surface is exposed from the receiving groove.

9. The device housing of claim 8, wherein the main body further comprises a battery accommodating cavity opposite to the rear surface, the battery accommodating cavity comprises an inner wall, the second surface and the inner wall cooperatively form the battery accommodating cavity.

10. A method for making a device housing, comprising:
providing a plate portion, the plate portion formed by punching a metal sheet into a predetermined shape;
injecting a first molten material in a mold to form a main body integrally formed on the plate portion;
injecting a second molten material in the mold to form at least one buffer body on the plate portion.

11. The method of claim 10, wherein the first molten material is plastic or resin.

12. The method of claim 10, wherein the second molten material is made of elastic material.

13. The method of claim 10, wherein the plate portion defines a groove, the at least buffer body is fixed on the plate portion opposite to the groove.

14. The method of claim 13, wherein the plate portion further defines a hole adjacent to the groove.

15. The method of claim 13, wherein at least one supporting portion is formed in the groove.

16. The method of claim 15, wherein the at least one supporting portion protrude and extend out of the groove until a surface of the at least one supporting portion is level with the other area of the second surface without the groove.
